(19) United States
(12) Patent Application Publication
(10) Pub. No.: US 2025/0038082 A1
(43) Pub. Date: Jan. 30, 2025

(54) PACKAGE WITH RECESS FOR BALANCING CREEPAGE CURRENT PATHS

(71) Applicant: Infineon Technologies AG, Neubiberg (DE)

(72) Inventors: Edward FÜRGUT, Dasing (DE); Dexter Inciong REYNOSO, Sinapore (SG); Uwe SCHINDLER, Reichenbach (DE); Frank SINGER, Regenstauf (DE)

(73) Assignee: Infineon Technologies AG, Neubiberg (DE)

(21) Appl. No.: 18/769,552

(22) Filed: Jul. 11, 2024

(30) Foreign Application Priority Data
Jul. 26, 2023 (DE) 10 2023 207 148.7

(51) Int. Cl. H01L 23/498; H01L 21/56; H01L 23/31; H01L 23/495

(52) U.S. Cl. CPC H01L 23/49811; H01L 21/563; H01L 23/3114; H01L 23/4951; H01L 23/49548

(57) ABSTRACT

A package is disclosed. In one example, the package includes a carrier, an electronic component mounted on the carrier, an encapsulant fully encapsulating the electronic component and the carrier, electrically conductive leads electrically coupled with the carrier and/or with the electronic component and extending out of the encapsulant at opposing sides of the encapsulant, and a recess in at least one of two opposing main surfaces of the encapsulant and extending between two opposing further sides of the encapsulant. A difference between a creepage current path length including the recess and a further creepage current path is not more than 20%.

### CROSS-REFERENCE TO RELATED APPLICATION

This Utility Patent application claims priority to German Patent Application No. 10 2023 207 148.7 filed Jul. 26, 2023, which is incorporated herein by reference.

### BACKGROUND

### Technical Field

Various embodiments relate generally to a package, and a method of manufacturing a package.

### Description of the Related Art

A conventional package may comprise an electronic component mounted on a chip carrier, may be electrically connected by a bond wire extending from the chip to the chip carrier or to a lead, and may be molded using a mold compound as an encapsulant.

Electric reliability of a conventional package may be an issue.

### SUMMARY

There may be a need for a package with high electric reliability and reasonable or low manufacturing effort.

According to an exemplary embodiment, a package is provided which comprises a carrier, an electronic component mounted on the carrier, an encapsulant fully encapsulating the electronic component and the carrier, electrically conductive leads electrically coupled with the carrier and/or with the electronic component and extending out of the encapsulant at opposing sides of the encapsulant, and a recess in at least one of two opposing main surfaces of the encapsulant and extending between two opposing further sides of the encapsulant, wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

According to another exemplary embodiment, a method of manufacturing a package is provided, the method comprising mounting an electronic component on a carrier, fully encapsulating the electronic component and the carrier by an encapsulant, electrically coupling electrically conductive leads with the carrier and/or with the electronic component, wherein the leads extend out of the encapsulant at two opposing sides of the encapsulant, and forming a recess in at least one of two opposing main surfaces of the encapsulant so as to extend between two opposing further sides of the encapsulant, wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

According to an exemplary embodiment, a package comprises a carrier carrying an electronic component, wherein an encapsulant fully encapsulates electronic component and carrier. Furthermore, leads extending at two opposing sides beyond the encapsulant are electrically coupled with carrier and/or electronic component. At least one recess in one or both of two opposing main surfaces of the encapsulant extends partially or entirely between two opposing further sides of the encapsulant, wherein said sides and said further sides may be angled with respect to each other. Advantageously, a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length. To put it shortly, the recess may be shaped and dimensioned so that minimum path lengths of a parasitic creepage current flowing between opposing leads along a top side and along a bottom side, respectively, of the package may differ from each other at the maximum by ±20%. Consequently, creepage distances along both opposing main surfaces of the package may be largely or even entirely balanced by an appropriate recess design so that a substantially homogeneous electric performance may be obtained over the entire package extension. Advantageously, a high electric reliability may be obtained without an undesired increase of the package dimensions. In particular, electric weak points in terms of electric reliability may be avoided. Consequently, the package may be designed for a high voltage class, for instance of at least 1200V. In addition to its creepage current path length balancing and increasing effects, the recess may render the creepage current trajectory between the two opposing leads also more complex, which may further contribute to a suppression of creepage current.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment.

FIG. 2 illustrates a flowchart of a method of manufacturing a package according to an exemplary embodiment.

FIG. 3 illustrates a side view of a package according to an exemplary embodiment.

FIG. 4 illustrates a three-dimensional view and a detail of the package according to FIG. 3.

FIG. 5 illustrates a three-dimensional view of a structure used for manufacturing packages according to an exemplary embodiment.

FIG. 6 illustrates a three-dimensional view of a structure used for manufacturing packages according to an exemplary embodiment.

FIG. 7 illustrates a plan view of structures obtained during manufacturing packages according to an exemplary embodiment.

FIG. 8 illustrates a cross-sectional view of a package according to another exemplary embodiment.

FIG. 9 illustrates a cross-sectional view of a package according to still another exemplary embodiment.

FIG. 10 illustrates a cross-sectional view of a package according to yet another exemplary embodiment.

FIG. 11 illustrates a cross-sectional view of a sidewall of a package according to another exemplary embodiment.

FIG. 12 illustrates a cross-sectional view of a sidewall of a package according to still another exemplary embodiment.

FIG. 13 illustrates a cross-sectional view of a sidewall of a package according to yet another exemplary embodiment.

FIG. 14 illustrates a plan view of structures obtained during manufacturing packages according to another exemplary embodiment.

### DETAILED DESCRIPTION

There may be a need for a package with high electric reliability and reasonable or low manufacturing effort.

According to an exemplary embodiment, a package is provided which comprises a carrier, an electronic component mounted on the carrier, an encapsulant fully encapsulating the electronic component and the carrier, electrically conductive leads electrically coupled with the carrier and/or with the electronic component and extending out of the encapsulant at opposing sides of the encapsulant, and a recess in at least one of two opposing main surfaces of the encapsulant and extending between two opposing further sides of the encapsulant, wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

According to another exemplary embodiment, a method of manufacturing a package is provided, the method comprising mounting an electronic component on a carrier, fully encapsulating the electronic component and the carrier by an encapsulant, electrically coupling electrically conductive leads with the carrier and/or with the electronic component, wherein the leads extend out of the encapsulant at two opposing sides of the encapsulant, and forming a recess in at least one of two opposing main surfaces of the encapsulant so as to extend between two opposing further sides of the encapsulant, wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

According to an exemplary embodiment, a package comprises a carrier carrying an electronic component, wherein an encapsulant fully encapsulates electronic component and carrier. Furthermore, leads extending at two opposing sides beyond the encapsulant are electrically coupled with carrier and/or electronic component. At least one recess in one or both of two opposing main surfaces of the encapsulant extends partially or entirely between two opposing further sides of the encapsulant, wherein said sides and said further sides may be angled with respect to each other. Advantageously, a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length. To put it shortly, the recess may be shaped and dimensioned so that minimum path lengths of a parasitic creepage current flowing between opposing leads along a top side and along a bottom side, respectively, of the package may differ from each other at the maximum by ±20%. Consequently, creepage distances along both opposing main surfaces of the package may be largely or even entirely balanced by an appropriate recess design so that a substantially homogeneous electric performance may be obtained over the entire package extension. Advantageously, a high electric reliability may be obtained without an undesired increase of the package dimensions. In particular, electric weak points in terms of electric reliability may be avoided. Consequently, the package may be designed for a high voltage class, for instance of at least 1200V. In addition to its creepage current path length balancing and increasing effects, the recess may render the creepage current trajectory between the two opposing leads also more complex, which may further contribute to a suppression of creepage current.

### Description of Further Exemplary Embodiments

In the following, further exemplary embodiments of the package and the method will be explained.

In the context of the present application, the term “package” may particularly denote an electronic device which may comprise one or more electronic components mounted on a (in particular electrically conductive) carrier. Said constituents of the package may be encapsulated by an encapsulant. Optionally, one or more electrically conductive interconnect bodies (such as metallic pillars, pumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). When the electronic component is a power device, it can for instance be a switch, a gate driver, or a functional combination (for instance an intelligent power module (IPM), or a smart intelligent power module (smart IPM). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, silicon-on-insulator (SOI) technology, gallium nitride technology, silicon carbide technology, etc.

In the context of the present application, the term “encapsulant” may particularly denote a substantially electrically insulating material surrounding an electronic component and a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “main surface” of the encapsulant may particularly denote an encapsulant surface of one of the largest encapsulant surfaces, more particularly an encapsulant surface of one of the two largest encapsulant surfaces. For instance, the encapsulant may have two opposing main surfaces separated by encapsulant material, carrier(s) and electronic component(s) in a thickness direction and connected with each other by a circumferential edge defined by a plurality of sides.

In the context of the present application, the term “sides” of the encapsulant may particularly denote sidewall sections of the encapsulant which may define a circumference of the encapsulant between its opposing main surfaces. Said sides may be oriented in a curved, slanted or orthogonal way with respect to a corresponding main surface. In particular, four sides of the encapsulant may be defined which may be grouped in two groups of two opposing sides each.

In the context of the present application, the term “leads” may in particular denote electrically conductive, in particular metallic, elongate structures which extend partially inside and partially outside of the encapsulant for establishing an electric connection between the encapsulated electronic component and an exterior of the package. Preferably, two leads or even two sets of leads may extend out of two opposing sides of the encapsulant, whereas the remaining further two opposing sides of the package may be free of leads. For example, leads may be straight or curved (for instance in a gull wing shape).

In the context of the present application, the term “recess” may in particular denote any indentation, channel, groove, blind hole, trench and/or cavity in a main surface of an encapsulant extending along part of or preferably along an entire distance between two opposing sides of the encapsulant. A recess may also be formed between two parallel ridges. It is also possible that a plurality of recesses is formed in such a main surface or that one or more recesses are formed in each of the two opposing main surfaces of the encapsulant. Descriptively speaking, such a recess may act for extending the creepage current path length between two opposing leads along a main surface of the encapsulant, since the creepage current must flow along an entire path between the leads including an extra surface portion added by the recess. In addition to at least one recess, a respective main surface of the encapsulant may optionally include at least one protrusion which may additionally contribute to an extension of the creepage current path length. It is also possible that a main surface being free of a recess comprises at least one protrusion. Furthermore, a main surface of the encapsulant may also be entirely flat.

In the context of the present application, the term “creepage current path length between two leads along a main surface of an encapsulant” may in particular denote the minimum length of a path along which a creepage current must flow on an encapsulant surface to bridge the entire spatial range between two opposing leads on two opposing sides of the encapsulant. When a recess is formed in one main surface of the encapsulant, the creepage current path length along said main surface includes an extra section defined by the surface trajectory of the recess.

In the context of the present application, the term “a difference between a creepage current path length (A) from one lead extending out of the encapsulant at one of said two opposing sides along one of said main surfaces and said recess up to another lead extending out of the encapsulant at the other one of said two opposing sides differs from a further creepage current path length (B) from said lead along the other one of said main surfaces up to said other lead by not more than 20% of said creepage current path length (A)” may in particular denote that a ratio between an absolute value of A-B and A is not more than 0.2.

In an embodiment, the sidewalls at the two opposing sides of the encapsulant are at least partially curved. The surface profile of said sidewalls, at which the leads extend out of the encapsulant, may be defined by an encapsulation tool, such as a mold tool.

In an embodiment, an exposed surface of the encapsulant at sidewalls at the two opposing sides has protrusions formed by filler particles covered with a mold skin. For example, the encapsulant may be a mold compound comprising a mold matrix material (for instance comprising an epoxy resin) filled with filler particles (for example for adjusting the thermal properties of the encapsulant). When the shape of said sidewalls is defined by a mold tool, the exterior appearance of the sidewall may show portions of mold matrix material and portions of filler particles coated with a thin layer of mold matrix material. Hence, such a surface configuration of said sidewalls may be a fingerprint of a definition of the sidewalls by a mold tool.

In an embodiment, the sidewalls at the two opposing further sides of the encapsulant are vertical. Said two opposing further sides, which may be free of leads, may be formed and defined by dicing, such as mechanically dicing or laser dicing. Consequently, said further sidewalls may be planar vertical surface portions of the encapsulant. Defining said further sidewalls by dicing may simplify the manufacturing process. Also indentations delimited by a curved surface may be present at an exterior surface of the further sides and may result from former filler particles which are removed out of mold matrix material by dicing, in particular by mechanically dicing.

In an embodiment, an exposed surface of the encapsulant at sidewalls at the two opposing further sides has at least one of protrusions formed by exposed filler particles, indentations delimited by a curved surface, cut filler particles in flush with a mold matrix material of the encapsulant, and heat affected features (for example a carbonization, carbon black, etc.). In particular, protrusions formed by exposed filler particles may be created by laser dicing (for instance using a nanosecond laser), when a laser beam burns away mold matrix material while leaving exterior filler particles intact. Additionally or alternatively, an exterior surface of said further sides of the encapsulant may comprise cut filler particles in flush with a mold matrix material of the encapsulant. When a sharp mechanical cutting blade or a femtosecond laser cuts through the encapsulant, it may also cut away parts of filler particles so that a flat exterior surface portion may remain which is partially defined by mold matrix material and partially by cut filler particles. Furthermore, heat affected features may be present at a respective one of said further sides, such as a carbonization created by a laser beam when interacting with encapsulant material.

In an embodiment, the package is configured as tie bar-less package. In an advantageous embodiment, no tie bar may be present at all in the package or no tie bar may extend to the exterior surface of the package. Thus, an outline of the package may be free of a tie bar. Tie bars may be used for interconnecting constituents of different packages during manufacture. In many cases, tie bars are made of metal, and may for example form part of a leadframe. During separating individual packages manufactured in a batch procedure, said tie bars may be separated as well. However, cutting through metallic tie bar material may be cumbersome and may decelerate the separation process. According to exemplary embodiments, tie bars may be omitted at all or at least in regions in which packages are singularized by dicing.

In an embodiment, the recess is formed in a main surface of the encapsulant facing the carrier and facing away from the electronic component. Such a design may increase the distance between the exterior surface of the encapsulant and the electronic component for protecting the latter. Additionally or alternatively, a recess may be formed in a main surface of the encapsulant facing away from the carrier and facing the electronic component.

In an embodiment, the package comprises a further recess in at least one of the two opposing main surfaces of the encapsulant and extending between the two opposing further sides of the encapsulant. By providing a plurality of recesses in one or both of the main surfaces of the encapsulant, the extension and balancing of the creepage current path length(s) may be further refined.

In an embodiment, the further recess is formed in the same main surface as the recess and extends in parallel to the recess. Thus, a plurality of recesses may be formed in the same main surface of the encapsulant to thereby increase on this side of the encapsulant the creepage current path length significantly, for instance for balancing out even enormous differences in the creepage current path lengths between both main surfaces. For example, a plurality of recesses may be formed parallel to each other on said same main surface to require a creepage current to flow along a wavy path for bridging the entire space between the two opposing leads. This may provide an exceptionally reliable protection against undesired creepage current.

In another embodiment, the further recess and the recess are formed in two opposing main surfaces of the encapsulant and extend in parallel to each other. Also in such a configuration, recess and further recess may be configured to adjust the above-mentioned difference between the creepage current path lengths to be not more than 20% of the creepage current path length along one main surface of the encapsulant. Furthermore, the provision of a respective recess on each of the two opposing main surfaces may render each respective creepage current path more complex to thereby strongly suppress creepage current flow between opposing leads along both main surfaces. This may additionally improve the electric reliability of the package.

In an embodiment, the leads are spaced from the recess by ridges of the encapsulant which delimit the recess laterally. When forming the recess in a central portion of the main surface of the encapsulant so as to extend along the entire distance between both further sides, two ridges are formed between said sides and the recess. Descriptively speaking, such ridges may make it even more complicated for a creepage current to flow between the leads on the two sides, which may further improve the electric reliability.

In an embodiment, at least parts of the leads extending outside of the encapsulant are at least partially bent towards the main surface of the encapsulant in which the recess is formed. For example, such bent leads may be gull wing-type leads. The main surface of the package towards which the leads are bent may be more prone to creepage current, so that the formation of the recess on the corresponding side of the encapsulant may be preferred.

In an embodiment, the recess extends along the entire distance between the two opposing further sides of the encapsulant, i.e. from one further side up to the other further side. Thus, the whole transverse range of the main surface having such a recess may be protected against creepage current, since the creepage current cannot flow around the recess in such a configuration.

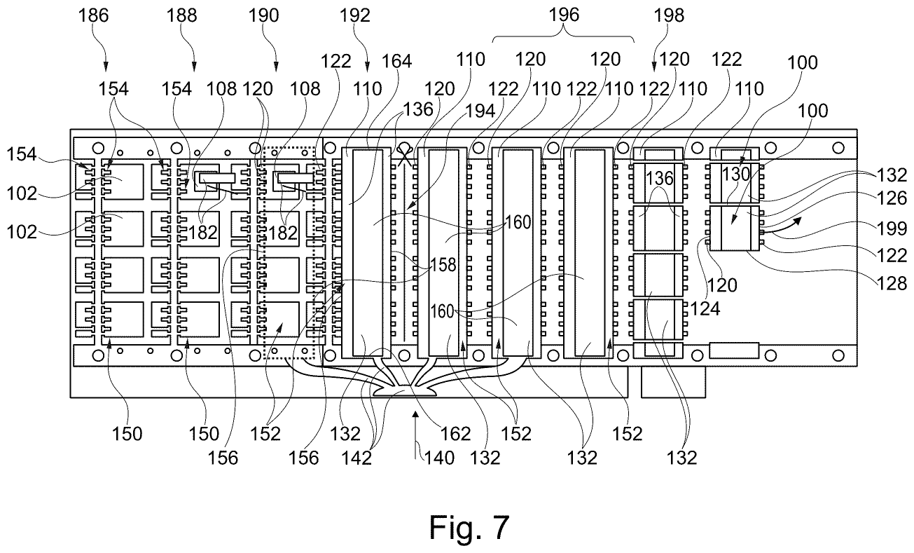

In an embodiment, the recess is a groove, for example a straight groove. Such a groove may be an elongate indentation extending preferably straight (alternatively curved, in a zigzag fashion, meandric, or wavy) and preferably along the entire extension (alternatively only along a sub portion) between the further sides. Such a groove may be manufactured in a very simple way by a batch molding process, as described referring to FIG. 7.

In an embodiment, a ratio between a width and a depth of the recess is at least 2, for example at least 5. Hence, the recess may be wide and shallow. A length of the recess between said further sides may be larger than both the width and the depth.

In an embodiment, said difference is not more than 10% of said creepage current path length. When the difference is at the maximum 10% or preferably at the maximum 5%, the creepage current flow characteristics along different main surfaces of the package may be almost completely balanced or equilibrated to thereby provide an excellent electric reliability. In a particular preferred embodiment, said difference is zero or at least less than 1%.

In an embodiment, a vertical distance between an exterior surface of the encapsulant delimited by the recess and a facing surface of the carrier is less than 400 μm, in particular is in a range from 100 μm to 300 μm. Thus, a remaining isolation thickness of the encapsulant (in particular a mold compound) below the carrier (such as a die pad) can be very small, leading to a compact design of the package without compromising on electric reliability. By forming the encapsulant of a respective package as a portion of a common bar-shaped encapsulant body formed for a plurality of packages together, said thickness may be reduced compared with conventional approaches without the risk of an isolation failure. This is due to a mold flow parallel to the recess, which allows to reliably fill even tiny spaces between a recess defining mold tool and a bottom of the carrier.

In an embodiment, the method comprises supplying flowable encapsulant material for forming the encapsulant along a direction corresponding to an extension of the recess. When transporting liquid or viscous mold compound (or another encapsulant material) along a direction which corresponds to the extension of the recess, both the formation of creepage path-extending ridges delimiting the recess laterally as well as the formation of an encapsulant isolation below the carrier may be reliably ensured. This improves the electric performance of the package and its reliability as a whole. Furthermore, such a manufacturing process is fully compatible with a batch formation of multiple packages at the same time on the basis of a common encapsulant structure, as described below in further detail. Hence, the described measure may also improve the efficiency and throughput of the package manufacture.

In an embodiment, the method comprises forming the package together with further packages in a batch manufacturing process which comprises mounting a plurality of electronic components on a plurality of carriers of a common carrier structure, fully encapsulating the electronic components and the carriers by a plurality of encapsulants of a common oblong encapsulant structure, electrically coupling a plurality of electrically conductive leads of a common lead structure with the carriers and/or with the electronic components so that the lead structure extends out of the encapsulant structure at two opposing sides of the encapsulant structure, and forming a plurality of recesses of a common recess structure in at least one of two opposing main surfaces of the encapsulant structure so that the common recess structure extends between two opposing further sides of the encapsulant structure. Such a highly advantageous manufacturing process will be described below in further detail referring to FIG. 5 to FIG. 7. To put it shortly, a plurality of electronic components may be assembled on a matrix-like arrangement of carriers and may be electrically coupled to assigned leads of a common lead structure. Thereafter, component-carrier-pairs of a common row may be covered by a common oblong encapsulant structure, for instance by molding. A plurality of parallel common oblong encapsulant structures may be formed simultaneously. Thus, this encapsulation process may be executed for a plurality of rows simultaneously. During encapsulation, common recess structures may be formed, at least one for each row, to thereby form the above-described recesses for individual packages by a corresponding shape of an encapsulation tool. Thereafter, the individual packages may be separated by separation processes executed along rows and columns.

In an embodiment, the method comprises separating the packages by disconnecting, for example by punching, the leads of the common lead structure outside of the common encapsulant structure. Said disconnection may be carried out along the same direction along which also the oblong encapsulant structure is formed. Preferably, no punching through other constituents of the packages than the leads needs to be done.

In an embodiment, the method comprises separating the packages by disconnecting, for example by dicing, in particular mechanical dicing and/or laser dicing, the common encapsulant structure along a separation direction corresponding to an extension direction of the leads. Said further disconnection may be carried out along a direction perpendicular to another direction along which also the oblong encapsulant structure is formed. Preferably, said separating process is executed without cutting through metallic tie bars, i.e. preferably cutting through encapsulant material only, which may accelerate the separation.

The combination of the two aforementioned separation processes allows a fast, simple and precise separation of the individual packages.

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Also a Smart IPM is possible (including a microcontroller). The package may also provide connectivity features, for instance WiFi, Bluetooth, etc. Another exemplary embodiment of the package is a dual inline package (DIP).

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning isolation are particularly pronounced for power dies. Also in the context of driver technologies which are handling high voltages (for example an insulated gate driver, level shifter gate drivers, solid state relays, circuit breakers, etc.), exemplary embodiments may provide significant advantages.

In an embodiment, the carrier comprises a leadframe-type die pad. A leadframe may be a metal structure inside the package that carries signals from the electronic component to the outside, and/or in opposite direction. The leadframe may comprise a central die pad, on which the electronic component is placed, surrounded by leads, i.e. metal conductors leading away from the electronic component to the electronic delivery of the package, and/or in opposite direction.

In an embodiment, the encapsulant encapsulates the electronic component and the carrier so that neither the front side nor the back side is exposed beyond the encapsulant. Hence, the package may have an outline defined exclusively by the encapsulant and by one or more leads extending out of the encapsulant for electric connection of the encapsulated at least one electronic component. Such a package may have an excellent electric reliability thanks to its circumferential dielectric encapsulation.

In an embodiment, the package comprises an electrically conductive coupling element electrically coupling the electronic component with the carrier and/or with at least one lead. Such an electrically conductive coupling element may be a clip, a bond wire, a bond ribbon and/or a flip chip interconnect element. A clip may be a curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the carrier and/or a lead or connecting different pads of an electronic component.

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

The technology of manufacturing leaded packages is moving into ultra high-density areas. A reason for this is the goal of highest material utilization and the increase of manufacturing flexibility. A further reduction of the manufacturing effort may involve the use of an encapsulant which has a higher creep resistance.

In parallel to this, power semiconductors are being deployed for increasing application voltage and more and more challenging isolation requirements (in particular defined by standards and regulations). This trend may lead to larger packages which is however in contradiction to the desired more efficient material utilization and the need of reduced manufacturing effort.

However, the possibility of reducing the creep resistance of a mold compound reaches technological limits. Moreover, a constant application voltage increases from 600V to 1200V and even to 1600V and 2000V. In particular, a package according to an exemplary embodiment may be compatible with an application voltage of up to at least 3.3 kV, up to at least 10 kV, up to at least 15 kV or even higher. Especially a creepage resistance with respect to an external voltage (such as a lightning strike) may be achievable. A required clearance distance may increase with increasing breakdown voltage and with increasing frequency. Furthermore, specific applications such as welding, aerospace, aviation, medical devices, etc. may require operation in higher pollution degrees, such as PD3.

Furthermore, conventional discrete leaded packages may experience different creeping distances between a top cavity and a bottom cavity. This may lead to inhomogeneous electric properties of conventional packages.

According to an embodiment, a package is provided with a carrier (such as a leadframe-type die pad) on which an electronic component (for instance a semiconductor power chip) is assembled. An encapsulant, for instance a mold compound with filler particles, encapsulates electronic component and carrier completely. One or more leads may extend out of the encapsulant at opposing sides thereof. Said leads may be electrically connected with the carrier and/or with the electronic component, for instance by one on more bond wires and/or clips. At least one of two opposing main surfaces of the encapsulant may be equipped with a (preferably longitudinal) recess which extends between two opposing further sides of the encapsulant, at which further sides no leads are present. Preferably, a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% (preferably by not more than 10% or not more than 5%) of said creepage current path length. In other words, the creepage current path length minus the further creepage current path length divided by the creepage current path length may be not more than ±20%, for example not more than ±10%. As a result, a creepage distance equilibration between opposing main surfaces of the package may be achieved thanks to the recess. This promotes, with simple measures, a high electric reliability and a high electric performance. Thus, electric weak points prone to creepage current flow may be avoided over the entire package, which allows to operate the package with high voltage. Advantageously, this may be achieved without increasing the volume of the package, which can therefore be manufactured with low effort.

More specifically, an exemplary embodiment may provide a high voltage discrete power package with properly balanced and increased creepage distance. In particular, an exemplary embodiment may increase the creepage distance in a discrete power package by creating a recess embodied as molded cavity on its bottom side.

In a specific embodiment, a discrete power package may be equipped with gull wing-type leads having a recess or cavity on its bottom side made by molding. A recess or groove may be arranged partly underneath a die pad-type carrier, which may result in an increase of the creepage distance. For example, the formation of the recess or cavity can be done on the top side and/or on the bottom side of the encapsulant, so as to achieve a balanced creepage distance between top and bottom cavity. Also multiple recesses or cavities can be formed on a single side or main surface of the encapsulant. Preferably, the recess or cavity may be formed over multiple packages by molding. The recess may be formed over the entire length of the mold structure (which may be formed in an ultra high-density fashion). Advantageously, the recess or cavity may be terminated by a sawing or a laser cutting process on both sides of the packages. Ridges formed by the recess in between may be straight without mold release angles. Furthermore, the formation of a creepage recess or cavity may increase the creepage distance on one side making said creepage distance equal to the creepage distance on the other side. Preferably, the package of an exemplary embodiment may be tie bar-less.

Exemplary embodiments may allow to produce smaller packages with excellent electric reliability. Hence, a package can be realized more compact without compromising on package performance. Alternatively, a package can be rendered more robust on the same footprint.

In an embodiment, a discrete power package may be equipped with gull wing leads and with a molded recess or groove area, preferably on the bottom side and at least partly underneath a die pad-type package to increase a resulting creepage distance for the package. Preferably, balanced creepage distances may be adjusted between top and bottom cavity by a corresponding recess design. In an embodiment, a creepage cavity may be infused over an entire length of the mold structure, for instance in the context of an ultra high-density technology. Hence, the recess or groove may be formed over multiple packages by molding. In a preferred embodiment, a creepage cavity may be terminated by a sawing or a laser cutting process on two package sides. Ridges formed as a consequence of the formation of a recess in between may be terminated by singulation without creating mold release angles. A creepage recess or cavity may be configured to increase the creepage distance to the level of the opposite side. In one embodiment, a creepage recess or cavity may be applied at a top and bottom cavity. It may also be advantageous to form a plurality of creepage recesses or cavities, for instance on one main surface of an encapsulant.

A package according to an exemplary embodiment may be configured for high voltage applications (for instance for a voltage class in a range from 600V to 2000V, for instance 1200V or more, at least 3.3 kV, at least 10 kV, or at least 15 kV). Such voltages may be provided for example by an external impact (such as a lightning strike). In such a package configuration, a creepage current flowing along an exterior surface of the package may create highly undesired parasitic electrically conductive paths which may involve issues. In order to reliably prevent such parasitic current paths extending along an exterior surface of the package, a creepage distance increasing recess may be formed at an exterior surface of the encapsulant and may be configured to balance out the length of a creepage current path along a top main surface and a bottom main surface to differ from each other by not more than ±20%, preferably by not more than ±10%, more preferably by not more than ±5%, and most preferably being identical within unavoidable technical tolerances. By a recess formed on at least one main surface of the package, such a design rule may be fulfilled without increasing device size and without compromising on electric reliability. Advantageously, a balanced creepage distance may be adjusted by a recess between top and bottom of an encapsulant, so that the difference between the creepage distances along the top side and along the bottom side of the package is strictly limited.

An exemplary embodiment may provide a dual side package with leads on two opposing sides, said leads relating to different voltage domains during operation of the package. A recess or groove, preferably underneath the package may lead to a more symmetrical and larger creepage distance of the package between leads on opposing sides. Preferably, the depth of the recess or groove may be limited to a minimum distance requirement so as to ensure maintenance of a sufficiently thick isolating mold layer between the bottom of the recess and the facing encapsulated carrier. Preferably, said minimum distance of said isolating mold layer may be in a range from 100 μm to 300 μm.

Exemplary applications of exemplary embodiments are gate drivers, power devices, intelligent power modules (in particular gate drivers with power switches), solid-state relays, etc.

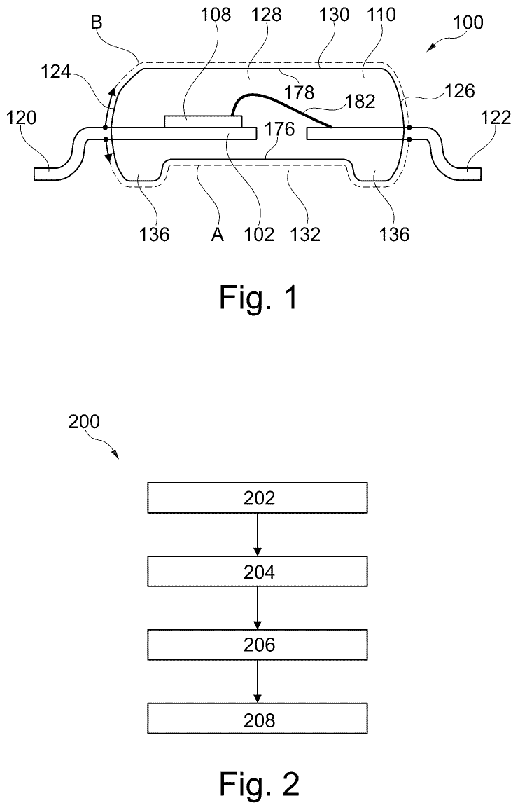

FIG. 1 illustrates a cross-sectional view of a package 100 according to an exemplary embodiment. Package 100 may be a discrete power semiconductor device.

Package 100 comprises a carrier 102. Carrier 102 can be embodied as a leadframe structure, for example may form part of a bent and punched metallic plate (for instance made of copper). Carrier 102 may be embodied as die pad carrying an electronic component 108. Electronic component 108 and/or carrier 102 may be electrically coupled with metallic leads 120, 122. Carrier 102 has a top-sided front side, on which the electronic component 108 is assembled, and an opposing bottom-sided back side facing away from the electronic component 108.

As shown, said electronic component 108 is mounted on the front side of the carrier 102. For example, the electronic component 108 may be a power semiconductor chip. For instance, at least one monolithically integrated circuit element (such as a diode or a transistor) may be monolithically integrated in a semiconductor substrate of the electronic component 108. Although only a single electronic component 108 is mounted on carrier 102 according to FIG. 1, it is also possible in other embodiments that a plurality of electronic components 108 are mounted on the front side of the carrier 102. For instance, the one or more electronic components 108 may be mounted on the carrier 102 by soldering, by sintering or by gluing.

A bottom-sided pad (not shown) of electronic component 108 may be electrically coupled with lead 120 which may be integrally formed with the die pad. A top-sided pad (not shown) of electronic component 108 may be electrically coupled with further lead 122 being a body which is separate from the die pad-type carrier 102. Said electric coupling between the electronic component 108 and the further lead 122 may be accomplished by an electrically conductive connection element 182. In the shown embodiment, the electrically conductive connection element 182 is embodied as bond wire. Alternatively, electrically conductive connection element 182 may be a clip (not shown).

Still referring to FIG. 1, an encapsulant 110 encapsulates the entire electronic component 108 and the entire die pad-type carrier 102. In other words, the encapsulant 110 fully encapsulates the electronic component 108 and the carrier 102. Furthermore, encapsulant 110 encapsulates part of the leads 120, 122. However, another part of the leads 120, 122 is exposed with respect to the encapsulant 110. The exposed metallic surface of the leads 120, 122 may function for electrically coupling the encapsulated electronic component 108 with an electronic periphery of package 100. Thus, the metallic leads 120, 122 are electrically coupled with the carrier 102 and/or with the electronic component 108 and extend out of the encapsulant 110 at two opposing sides 124, 126 or sidewalls of the encapsulant 110. Encapsulant 110 can be a mold compound which mechanically protects and electrically insulates the encapsulated electronic component 108.

Advantageously, a groove-type recess 132 extending perpendicular to the paper plane of FIG. 1 is formed in a lower main surfaces 176 of the encapsulant 110 and extends between two opposing further sides 128, 130 or sidewalls of the encapsulant 110. In the shown embodiment, the recess 132 is formed in the main surface 176 of the encapsulant 110 facing the carrier 102 and facing away from the electronic component 108. Further side 128 lies within the paper plane of FIG. 1, whereas further side 130 is arranged below or behind the paper plane of FIG. 1 and parallel to the further side 128. As shown as well in FIG. 1, the leads 120, 122 are laterally spaced from the recess 132 by two ridges 136 of the encapsulant 110 which delimit the recess 132 laterally. The parts of the gull wing-shaped leads 120, 122 extending outside of the encapsulant 110 are bent towards the main surface 176 of the encapsulant 110 in which the recess 132 is formed. Although not visible in FIG. 1, the recess 132 is embodied as a straight groove which extends along the entire distance between the two opposing further sides 128, 130 of the encapsulant 110. Such a recess 132 may be manufactured in a very simple and well-defined way by molding, as described below referring to FIG. 5 to FIG. 7.

In contrast to the profiled lower main surface 176, an upper main surface 178 of encapsulant 110 is flat, i.e. is free of a recess (although one or more recesses can be formed in the upper main surface 178 in other embodiments). Recess 132 in lower main surface 176 is shaped and dimensioned for at least partially balancing a difference between creepage current path lengths A, B between lead 120 and lead 122. Without recess 132, creepage current path length B would be significantly larger than creepage current path length A. Since recess 132 adds an extra path length contribution to creepage current path length A, creepage current path length A becomes more similar or even identical to creepage current path length B. More specifically, FIG. 1 illustrates that a parasitic creepage current can flow along a bottom side of encapsulant 110 from lead 120 along creepage current path length A to lead 122. FIG. 1 illustrates as well that a parasitic creepage current can flow along a top side of encapsulant 110 from lead 120 along further creepage current path length B to lead 122.

Thanks to the recess 132, the creepage current path lengths A, B are adjusted to match at least approximately. More specifically, the recess 132 may be shaped and dimensioned so that a difference between a shortest creepage current path length A from lead 120 extending out of the encapsulant 110 at one of said two opposing sides 124 along said main surface 176 and said recess 132 up to the other lead 122 extending out of the encapsulant 110 at the other one of said two opposing sides 126 differs from the shortest further creepage current path length B from said lead 120 along the other main surface 178 up to said other lead 122 by not more than 20%, preferably by not more than 10%, and more preferably by not more than 5% of said creepage current path length A. It may be most preferred that the at least one recess 132 is shaped and dimensioned so that a shortest bottom-sided creepage current path length A between the leads 120, 122 extending out of the encapsulant 110 at said two opposing sides 124, 126 equals to the shortest top-sided further creepage current path length B. When complying with at least one of the mentioned design rules concerning creepage current path length adjustment, electric weak points in terms of creepage current may be avoided around the entire exterior surface of encapsulant 110, leading to a high electric reliability and high electric performance of package 100. At the same time, the provision of the one recess 132 extends the creepage current path length A and renders the corresponding creepage current path more complex, thereby further suppressing the risk of creepage current along the bottom side of package 100. Highly advantageously, these benefits may be achieved with simple measures and without increasing the size of the package 100. On the contrary, a highly compact package 100 with excellent electric properties may be obtained.

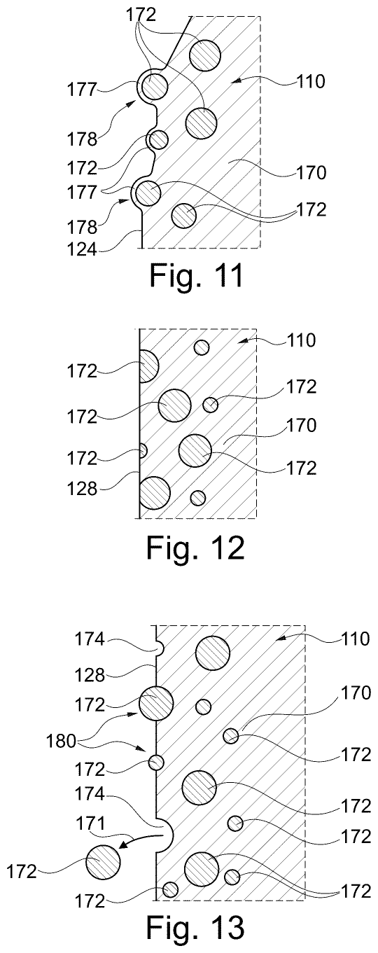

As shown, the sidewalls at the two opposing sides 124, 126 of the encapsulant 110 are curved. This may be achieved due to the definition of said opposing sides 124, 126 by a molding process described in further detail referring to FIG. 5 to FIG. 7. The surface of the sides 124, 126 may have the appearance as shown in FIG. 11.

In contrast to sides 124, 126, sidewalls at the two opposing further sides 128, 130 of the encapsulant 110 are vertical. This may be a fingerprint of the definition of the further sides 128, 130 by dicing. The surface of the further sides 128, 130 may have the appearance as shown in FIG. 12 when formed by mechanically dicing using a dicing blade (or when using a femtosecond laser with appropriately adjusted operation parameters). The surface of the further sides 128, 130 may have the appearance as shown in FIG. 13 when formed by laser dicing (in particular using a nanosecond laser).

Advantageously, the illustrated package 100 is configured as tie bar-less package, i.e. does not comprise tie bars strengthening the carrier 102 during manufacture of package 100. This may simplify in particular the separation process of the package 100 from a batch structure, since a separation can be accomplished by cutting through encapsulant material only. Alternatively, the package 100 may comprise one or more tie bars (not shown).

For example, the package 100 of FIG. 1 may be embodied as a DSO-type package. Package 100 of FIG. 1 may be appropriate for operation at a voltage of up to 1200V. For instance, the creepage distance between leads 120, 122 on the top side may be 5.48 mm, and the creepage distance between leads 120, 122 on the bottom side may be 5.48 mm.

FIG. 2 illustrates a flowchart 200 of a method of manufacturing a package 100 according to an exemplary embodiment. The reference signs used for the following description of said manufacturing method relate to the embodiment of FIG. 1.

Referring to a block 202, the method comprises mounting an electronic component 108 on a carrier 102.

Referring to a block 204, the method comprises fully encapsulating the electronic component 108 and the carrier 102 by an encapsulant 110.

Referring to a block 206, the method comprises electrically coupling electrically conductive leads 120, 122 with the carrier 102 and/or with the electronic component 108, wherein the leads 120, 122 extend out of the encapsulant 110 at two opposing sides 124, 126 of the encapsulant 110.

Referring to a block 208, the method comprises forming a recess 132 in at least one of two opposing main surfaces 176, 178 of the encapsulant 110 so as to extend between two opposing further sides 128, 130 of the encapsulant 110. A difference between a creepage current path length A from one lead 120 extending out of the encapsulant 110 at one of said two opposing sides 124 along one of said main surfaces 176 and said recess 132 up to another lead 122 extending out of the encapsulant 110 at the other one of said two opposing sides 126 differs from a further creepage current path length B from said lead 120 along the other one of said main surfaces 178 up to said other lead 122 by not more than 20% of said creepage current path length A.

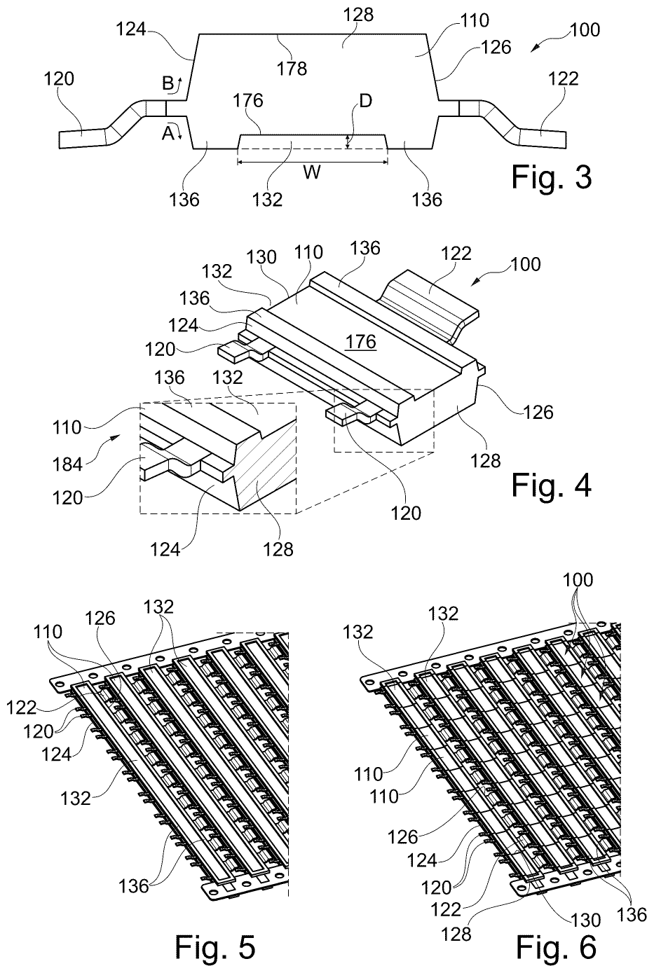

FIG. 3 illustrates a side view of a package 100 according to an exemplary embodiment. FIG. 4 illustrates a three-dimensional view and a detail 184 of the package 100 according to FIG. 3. The embodiment of FIG. 3 and FIG. 4 corresponds largely to the embodiment of FIG. 1.

As shown in FIG. 3, a ratio between a width W and a depth D of the recess 132 may be preferably at least 5. Thus, recess 132 may be wide and shallow and therefore does not influence the exterior outline of the package 100 significantly. Nevertheless, recess 132 may extend a corresponding creepage current path, may render the creepage current path more complex, and may balance the creepage current paths between leads 120, 122 along an upper side (see reference sign B) and along a lower side (see reference sign A). This may strongly suppress the risk of an undesired creepage current shorting leads 120, 122 unintentionally.

FIG. 4 illustrates that recess 132 extends as straight groove along the entire path between both opposing further sides 128, 130 and is laterally delimited between opposing straight and elevated ridges 136. This extends the creepage current path length and renders the creepage current path more complex, as also seen in detail 184 of FIG. 4.

FIG. 4 also shows that two leads 120 extend out of the encapsulant 110 at side 124, whereas only one lead 122 extends out of the encapsulant 110 at the opposing other side 126.

Package 100 according to FIG. 3 and FIG. 4 can be manufactured in a highly efficient way by a batch manufacturing process which will be described in the following referring to FIG. 5 to FIG. 7:

FIG. 5 illustrates a three-dimensional view of a structure used for manufacturing packages 100 according to an exemplary embodiment, before dicing. FIG. 6 illustrates another three-dimensional view of a structure used for manufacturing packages 100 according to an exemplary embodiment, after dicing. FIG. 7 illustrates a plan view of structures obtained during manufacturing packages 100 according to an exemplary embodiment.

First referring to FIG. 7, the manufacturing method comprises forming a plurality of packages 100 in a batch manufacturing process together and comprises the following processes:

As shown by reference sign 186, a common carrier structure 150 is provided which comprises a plurality of die pad-type type carriers 102 each being configured for assembling a respective one of electronic components 108. The common carrier structure 150 may be a structured metal plate, for instance made of copper, and may be embodied as a leadframe. A plurality of leads 120, 122 may form part of a common lead structure 154 which may be integrally formed with the common carrier structure 150.

As shown by reference sign 188, a plurality of electronic components 108 (such as discrete semiconductor power chips) may be mounted or assembled on the common carrier 150. Each electronic component 108 may be mounted on an assigned one of the carriers 102 of the common carrier structure 150. For instance, the electronic components 108 may be connected with the carriers 102 by soldering, sintering or gluing. Furthermore, the electronic components 108 may be electrically connected with one or more assigned leads 120, 122 by electrically conductive connection elements 182, such as bond wires and/or clips.

As shown by reference sign 190, the electronic components 108, the carriers 102 and the electrically conductive connection elements 182 may be fully encapsulated by a plurality of encapsulants 110 of a common oblong encapsulant structure 152. Simultaneously, the leads 120, 122 are only partially encapsulated by the common oblong encapsulant structure 152. Hence, the electrically conductive leads 120, 122 of the common lead structure 154 being electrically coupled with the carriers 102 and with the electronic components 108, respectively, are arranged so that the lead structure 154 extends out of the encapsulant structure 152 at two opposing sides 156, 158 of the encapsulant structure 152, see again reference sign 190. As shown, the encapsulation process comprises supplying flowable encapsulant material 142 into different flow paths simultaneously for forming the encapsulant 110 along a direction 140 corresponding to an extension of recesses 132.

As shown by reference sign 192, a plurality of recesses 132 of a common recess structure 160 are formed in at least one of two opposing main surfaces 176, 178, for example in main surface 176, of the encapsulant structure 152 so that the common recess structure 160 extends between two opposing further sides 162, 164 of the encapsulant structure 152. Formation of the common recess structure 160 may be carried out simultaneously with the encapsulation process. In the shown embodiment, the encapsulation process is a molding process. During said encapsulation process, a plurality of bar-shaped encapsulant bodies are formed as parallel common oblong encapsulant structures 152 extending in parallel to each other as bars. The result of the encapsulation process and the simultaneous formation of the common recess structures 160 is also shown in FIG. 5. Formation of the common recess structures 160 may be accomplished by a corresponding shape of a mold tool.

After encapsulation, exposed metal surfaces of leads 120, 122 may be subjected to optional plating.

As shown by reference sign 194, the method may proceed with separating the individual packages 100 by disconnecting them by punching the leads 120, 122 along an extension direction of the oblong common encapsulant structure 152. Thus, individual packages 100 may be separated by cutting along a first direction the leads 120, 122 of the common lead structure 154 outside of the common encapsulant structure 152. To put it shortly, the leads 120, 122 may be cut, for instance by punching.

As shown by reference sign 196, the method may proceed optionally with a testing and marking process.

As shown by reference sign 198, the method may then proceed with separating the packages 100 along a second direction being perpendicular to the first direction by disconnecting the packages 100 by dicing. For example, said second disconnection process may be realized by mechanical dicing (using a cutting blade for separation) and/or laser dicing (using a laser beam for separation). By said second separation process, the common encapsulant structure 152 may be separated along a separation direction parallel to an extension direction of the leads 120, 122. Advantageously, said second separation process may solely cut through encapsulant material, not through metallic material, which may significantly accelerate the separation process. The result of the dicing separation process is also shown in FIG. 6.

As shown by reference sign 199, the method may then proceed with packing the separated packages 100.

Advantageously, the manufacturing method described referring to FIG. 7 may allow to obtain a very high number of packages 100 per leadframe area. Thus, FIG. 7 relates to an ultra high-density manufacturing process.

Again, the design rule for manufacturing the common recess structures 160 may be that the corresponding recesses 132 ensure that, for each package 100, a difference between a creepage current path length A from one lead 120 extending out of the encapsulant 110 at one of said two opposing sides 124 along one of said main surfaces 176 and said recess 132 up to another lead 122 extending out of the encapsulant 110 at the other one of said two opposing sides 126 differs from a further creepage current path length B from said lead 120 along the other one of said main surfaces 178 up to said other lead 122 by not more than 20%, preferably by not more than 10%, more preferably by not more than 5%, of said creepage current path length A. Most preferred may be a configuration in which the recesses 132 ensure that the creepage current path lengths A and B are identical.

Descriptively speaking, the embodiment of FIG. 7 allows the formation of an infused flow adjusted groove or recess area. Bar-shaped common oblong encapsulant structures 152, which can be embodied as mold bars, may be provided with common recess structure 160 as cavity groove on the backside. The common recess structure 160 may extend along the same direction as the mold bar. Advantageously, an incorporation of a mold groove string within multiple packages allows the manufacture of an encapsulant bar layout. A package mold groove may be determined in length by a one-sided singulation process (in particular dicing or laser cutting). Advantageously, an increased creepage distance may be achieved due to a straight ridge design without mold release angles. Preferably, the packages 100 may be manufactured according to FIG. 7 in a tie bar-less fashion. Alternatively, one or more tie bars may be provided, if desired or required. Further advantageously, a balanced creepage distance of asymmetrical mold cavities may be realized with the described manufacturing architecture. Moreover, the described manufacturing concept may offer advantages in terms of warpage and torsion of the leadframe. Beyond this, less mold compound usage and waste may be achieved. The recess or groove direction may be the same as the mold flow direction, so that the formation of filigree structures may be possible. Furthermore, a simplified mold tool manufacturing process may become possible, and ejector pins can be placed within a recess area.

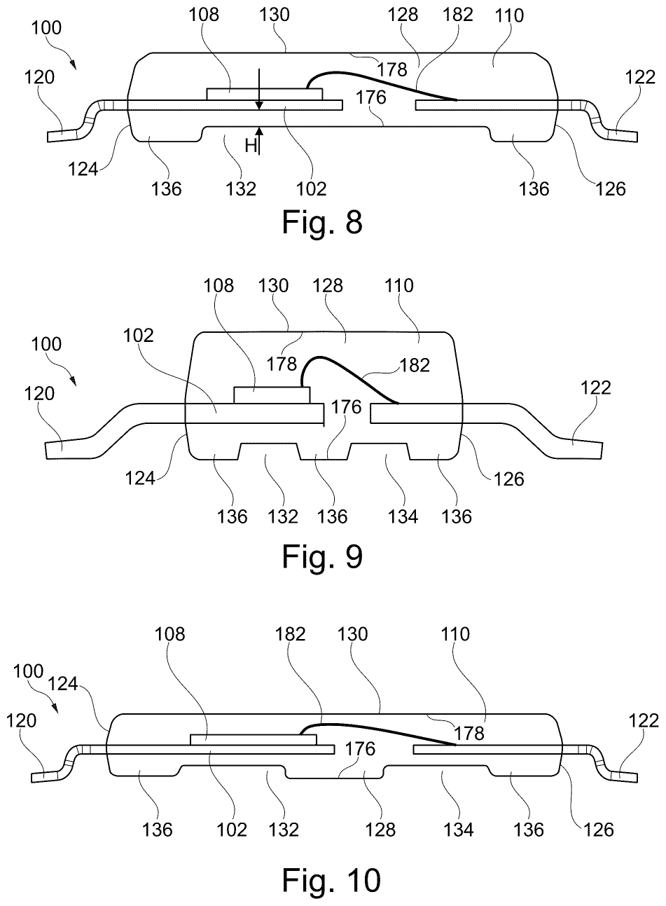

FIG. 8 illustrates a cross-sectional view of a package 100 according to another exemplary embodiment.

The embodiment according to FIG. 8 differs from the embodiment of FIG. 1 in particular in that, according to FIG. 8, a length to height ratio of the encapsulant 110 is significantly larger in FIG. 8.

Furthermore, FIG. 8 shows a vertical distance H between an exterior surface of the encapsulant 110 delimited by the recess 132 and a facing surface of the carrier 102. The vertical distance H may be less than 400 μm, and may be preferably in a range from 100 μm to 300 μm.

For example, the package 100 of FIG. 8 may be embodied as a DSO-type package. Package 100 of FIG. 8 may be appropriate for operation at a voltage of up to 1700V. For instance, the creepage distance on the top side may be 9.08 mm, and the creepage distance on the bottom side may be 9.08 mm.

FIG. 9 illustrates a cross-sectional view of a package 100 according to still another exemplary embodiment.

The embodiment according to FIG. 9 differs from the embodiment of FIG. 1 in particular in that, according to FIG. 9, a further recess 134 is formed in main surface 176 of the encapsulant 110 and extends between the two opposing further sides 128, 130 of the encapsulant 110. Recesses 132, 134 extend side-by-side and parallel to each other. Advantageously, the provision of multiple grooves or recesses 132, 134 may further extend the length of the creepage path along the bottom main surface 176 and may render the latter more complex for passage by a creepage current. Consequently, creepage current flow may be strongly suppressed according to the embodiment of FIG. 9.

For example, the package 100 of FIG. 9 may be embodied as an SOT223-type package. Package 100 of FIG. 9 may be appropriate for operation at a voltage of up to 1200V. For instance, the creepage distance on the top side may be 5.3 mm, and the creepage distance on the bottom side may be 5.3 mm.

FIG. 10 illustrates a cross-sectional view of a package 100 according to yet another exemplary embodiment.

The embodiment according to FIG. 10 differs from the embodiment of FIG. 1 in particular in that, according to FIG. 10, a length to height ratio of the encapsulant 110 is significantly larger in FIG. 10. Moreover, the embodiment according to FIG. 10 differs from the embodiment of FIG. 1 also in that, according to FIG. 10, a further recess 134 is formed in main surface 176 of the encapsulant 110 and extends between the two opposing further sides 128, 130 of the encapsulant 110. Recesses 132, 134 extend side-by-side and parallel to each other. Advantageously, the provision of multiple grooves or recesses 132, 134 may further extend the length of the creepage path and may render the latter more complex for passage by a creepage current. Consequently, creepage current flow may be strongly suppressed according to the embodiment of FIG. 10.

For example, the package 100 of FIG. 10 may be embodied as a DSO-type package. Package 100 of FIG. 10 may be appropriate for operation at a voltage of up to 2000V. For instance, the creepage distance on the top side may be 12.58 mm, and the creepage distance on the bottom side may be 13.12 mm.

Thus, the creepage current path lengths A, B are completely balanced and are identical in FIG. 8 and FIG. 9, whereas they are partially balanced according to FIG. 10.

FIG. 11 illustrates a cross-sectional view of a sidewall of a package 100 according to an exemplary embodiment. The curved package sidewall shown in FIG. 11 is defined by a molding process and corresponds to sides 124, 126.

As shown in FIG. 11, an exposed surface of the encapsulant 110 at sidewalls at each of the two opposing sides 124, 126 has protrusions 178 formed by intact filler particles 172 covered with a mold skin 177. In different embodiments, it is possible to use filler particles 172 of a homogeneous size, or filler particles 172 of different sizes (for example of two or three different sizes). For example, the encapsulant 110 may be a mold compound comprising a mold matrix material 170 (for instance comprising an epoxy resin) filled with filler particles 172 (for example ceramic filler particles, for instance silicon oxide and/or glass fillers, or filler particles made of aluminum oxide for enhancing thermal conductivity of the encapsulant 110). When the shape of said sidewall of sides 124, 126 is defined by a mold tool, the surface of the sidewall shows portions of mold matrix material 170 and portions of filler particles 172 coated with a thin layer of mold matrix material 170, so that a mold skin 177 coats the filler particles 172 at the exposed sidewall of sides 124, 126. For example, the mold skin 177 may have a thickness in a range from 1 μm to 10 μm, for example 5 μm.

FIG. 12 illustrates a cross-sectional view of a sidewall of a package 100 according to an exemplary embodiment. The straight vertical package sidewall shown in FIG. 12 is defined by a mechanical cutting process and corresponds to the above-mentioned further sides 128, 130.

As illustrated in FIG. 12, an exposed surface of the encapsulant 110 at sidewalls at the two opposing further sides 128, 130 has cut filler particles 172 in flush with mold matrix material 170 of the encapsulant 110. More specifically, first surface regions of sides 128, 130 are formed by planar surface portions of the filler particles 172, whereas second surface portions of sides 128, 130 are formed by planar surface portions of the mold matrix material 170. When a sharp mechanical cutting blade (or a femtosecond laser) cuts through the encapsulant 110, it may also cut away parts of filler particles 172 so that a flat exterior surface may remain which is partially defined by mold matrix material 170 and partially by cut filler particles 172.

FIG. 13 illustrates a cross-sectional view of a sidewall of a package 100 according to yet another exemplary embodiment. The straight vertical package sidewall shown in FIG. 13 is defined by a laser dicing process and corresponds to the above-mentioned further sides 128, 130.

According to FIG. 13, an exposed surface of the encapsulant 110 at sidewalls at the two opposing further sides 128, 130 has protrusions 180 formed by exposed filler particles 172. The protrusions 180 may be formed by exposed filler particles 172 and may be created by laser dicing (for instance using a nanosecond laser), when a laser beam burns away mold matrix material 170 while leaving exterior filler particles 172 intact. Furthermore, indentations 174 may be formed at the exposed surface of sides 128, 130 which are delimited by a curved surface corresponding to a curved surface of particles 172 which have fallen out of encapsulant 110 during the laser separation process, see reference sign 171. In addition, heat affected features may be visible at the exposed sidewall of encapsulant 110, for example a carbonization created by a laser beam.

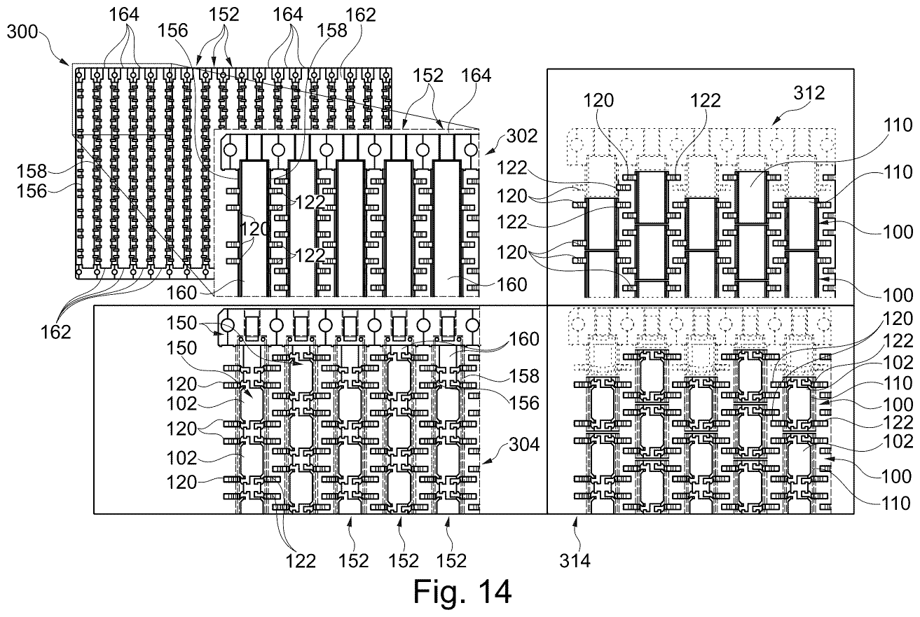

FIG. 14 illustrates a plan view of structures obtained during manufacturing packages 100 according to another exemplary embodiment. To put it shortly, the embodiment of FIG. 14 relates to interdigital leads 120, 122 in combination with laser singulation. Such an embodiment allows a batch manufacture of multiple packages 100 using bar-shaped encapsulant structures 152 provided for many packages 100 in common.

FIG. 14 shows a plan view 300 of a batch structure before separation into individual packages 100, a detail 302 of the plan view 300, and a transparent detail 304 of the plan view 300. Furthermore, FIG. 14 shows a detail 312 of a plan view of the batch structure after separation into individual packages 100, and a transparent detail 314 corresponding to the detail 312. Separation can be accomplished by laser processing according to FIG. 14.

The embodiment of FIG. 14 differs from the embodiment of FIG. 7 in particular in that, according to FIG. 14, the leads 120, 122 assigned to adjacent encapsulant structures 152 are not provided in flush with each other as in FIG. 7. In contrast to this, adjacent leads 120, 122 assigned to adjacent encapsulant structures 152 and arranged along a direction corresponding to the extension of the encapsulant structures 152 are displaced with respect to each other in an overlapping fashion transverse to the direction corresponding to the extension of the encapsulant structures 152 so as to form an interdigital leads arrangement, as illustrated in FIG. 14. This renders a separation of common lead structures 154 into leads 120, 122 dispensable according to FIG. 14, which simplifies the manufacturing process.

For executing the manufacturing process according to FIG. 14, a plurality of electronic components 108 are mounted on a plurality of carriers 102 of a common carrier structure 150. The electronic components 108 and the carriers 102 are encapsulated by a plurality of encapsulants 110 of parallel common oblong encapsulant structures 152. A plurality of electrically conductive leads 120, 122, here embodied as interdigital leads, are electrically coupled with the carriers 102 and with the electronic components 108 so that the leads 120, 122 extend out the encapsulant structure 152 at two opposing sides 156, 158 of the encapsulant structure 152. Furthermore, a plurality of recesses 132 of a common recess structure 160 may be formed in at least one of two opposing main surfaces 176, 178 of the encapsulant structure 152 so that the common recess structure 160 extends between two opposing further sides 162, 164 of the encapsulant structure 152. The encapsulant structures 152 may then be separated by laser cutting, wherein individual cutting lines may be displaced along a direction corresponding to the extension of the encapsulant structures 152, see details 312, 314. By this separation, the individual packages 100 may be obtained.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier;
an electronic component mounted on the carrier;
an encapsulant fully encapsulating the electronic component and the carrier;
electrically conductive leads electrically coupled with the carrier and/or with the electronic component and extending out of the encapsulant at two opposing sides of the encapsulant; and
a recess in at least one of two opposing main surfaces of the encapsulant and extending between two opposing further sides of the encapsulant,
wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

2. The package according to claim 1, comprising at least one of the following features:
wherein sidewalls at the two opposing sides of the encapsulant are at least partially curved;
wherein an exposed surface of the encapsulant at sidewalls at the two opposing sides has protrusions formed by filler particles covered with a mold skin.

3. The package according to claim 1, comprising at least one of the following features:
wherein sidewalls at the two opposing further sides of the encapsulant are vertical;
wherein an exposed surface of the encapsulant at sidewalls at the two opposing further sides has at least one of protrusions formed by exposed filler particles, indentations delimited by a curved surface, cut filler particles in flush with a mold matrix material of the encapsulant, and heat affected features.

4. The package according to claim 1, wherein the package is configured as tie bar-less package.

5. The package according to claim 1, wherein the recess is formed in a main surface of the encapsulant facing the carrier and facing away from the electronic component.

6. The package according to claim 1, wherein the recess is formed in a main surface of the encapsulant facing away from the carrier and facing the electronic component.

7. The package according to claim 1, comprising a further recess in at least one of the two opposing main surfaces of the encapsulant and extending between the two opposing further sides of the encapsulant.

8. The package according to claim 7, wherein the further recess is formed in the same main surface as the recess and extends in parallel to the recess.

9. The package according to claim 7, wherein the further recess and the recess are formed in two opposing main surfaces of the encapsulant and extend in parallel to each other.

10. The package according to claim 1, wherein the leads are spaced from the recess by ridges of the encapsulant which delimit the recess laterally.

11. The package according to claim 1, wherein at least parts of the leads extending outside of the encapsulant are at least partially bent towards the main surface of the encapsulant in which the recess is formed.

12. The package according to claim 1, wherein the recess extends along the entire distance between the two opposing further sides of the encapsulant.

13. The package according to claim 1, wherein the recess is a groove, for example a straight groove.

14. The package according to claim 1, comprising at least one of the following features:
wherein a ratio between a width and a depth of the recess is at least 2;
wherein said difference is not more than 10% of said creepage current path length (A);
wherein said difference is zero;
a vertical distance between an exterior surface of the encapsulant delimited by the recess and a facing surface of the carrier is less than 400 μm, in particular is in a range from 100 μm to 300 μm;
the leads are gull wing-shaped;
the package is configured as a power package;
the electronic component is a power chip;
the carrier comprises a leadframe-type die pad.

15. A method of manufacturing a package, the method comprising:
mounting an electronic component on a carrier;
fully encapsulating the electronic component and the carrier by an encapsulant;
electrically coupling electrically conductive leads with the carrier and/or with the electronic component, wherein the leads extend out of the encapsulant at two opposing sides of the encapsulant; and
forming a recess in at least one of two opposing main surfaces of the encapsulant so as to extend between two opposing further sides of the encapsulant;
wherein a difference between a creepage current path length from one lead extending out of the encapsulant at one of said two opposing sides along one of said main surfaces and said recess up to another lead extending out of the encapsulant at the other one of said two opposing sides differs from a further creepage current path length from said lead along the other one of said main surfaces up to said other lead by not more than 20% of said creepage current path length.

16. The method according to claim 15, wherein the method comprises supplying flowable encapsulant material for forming the encapsulant along a direction corresponding to an extension of the recess.

17. The method according to claim 15, wherein the method comprises forming the package together with further packages in a batch manufacturing process which comprises:
mounting a plurality of electronic components on a plurality of carriers of a common carrier structure;
fully encapsulating the electronic components and the carriers by a plurality of encapsulants of a common oblong encapsulant structure;
electrically coupling a plurality of electrically conductive leads of a common lead structure with the carriers and/or with the electronic components so that the lead structure extends out the encapsulant structure at two opposing sides of the encapsulant structure; and
forming a plurality of recesses of a common recess structure in at least one of two opposing main surfaces of the encapsulant structure so that the common recess structure extends between two opposing further sides of the encapsulant structure.

18. The method according to claim 17, wherein the method comprises separating the packages by disconnecting the leads of the common lead structure outside of the common encapsulant structure.

19. The method according to claim 15, wherein the method comprises forming the package together with further packages in a batch manufacturing process which comprises:
mounting a plurality of electronic components on a plurality of carriers of a common carrier structure;
fully encapsulating the electronic components and the carriers by a plurality of encapsulants of a common oblong encapsulant structure;
electrically coupling a plurality of electrically conductive leads with the carriers and/or with the electronic components so that the leads extend out the encapsulant structure at two opposing sides of the encapsulant structure; and
forming a plurality of recesses of a common recess structure in at least one of two opposing main surfaces of the encapsulant structure so that the common recess structure extends between two opposing further sides of the encapsulant structure.

20. The method according to claim 17, wherein the method comprises separating the packages by disconnecting common encapsulant structure, along a separation direction corresponding to an extension direction of the leads.
